(19) United States
(12) Patent Application Publication
(10) Pub. No.: US 2015/0267295 A1
(43) Pub. Date: Sep. 24, 2015

(54) REMOVABLE SUBSTRATE TRAY AND ASSEMBLY AND REACTOR INCLUDING SAME

(71) Applicant: ASM IP Holding B.V., Almere (NL)

(72) Inventors: Eric Hill, Phoenix, AZ (US); John Tolle, Phoenix, AZ (US); Matthew Goodman, Phoenix, AZ (US)

(73) Assignee: ASM IP Holding B.V., Almere (NL)

(21) Appl. No.: 14/219,879

(22) Filed: Mar. 19, 2014

(51) Int. Cl. C23C 16/458; C23C 16/455; H05B 6/10

(52) U.S. Cl. CPC C23C 16/4581; H05B 6/105; C23C 16/4583; C23C 16/4586; C23C 16/45557

(57) ABSTRACT

A substrate tray, a susceptor assembly including a substrate tray, and a reactor including a substrate tray and/or susceptor assembly are disclosed. The substrate tray is configured to retain a substrate during processing and can be formed of a substantially non-reactive material. The substrate tray can be received by a susceptor, formed of another material, to form the susceptor assembly.

### FIELD OF INVENTION

The present disclosure generally relates to gas-phase reactors and systems. More particularly, the disclosure relates to substrate trays for retaining one or more substrates within a gas-phase reactor, to assemblies including the trays, and to reactors and systems including the trays and assemblies.

### BACKGROUND OF THE DISCLOSURE

Gas-phase reactors, such as chemical vapor deposition (CVD), plasma-enhanced CVD (PECVD), atomic layer deposition (ALD), and the like can be used for a variety of applications, including depositing and etching materials on a substrate surface. FIG. 1 illustrates a typical gas-phase reactor system 100, which includes a reactor 102, including a reaction chamber 104, a susceptor 106 to hold a substrate 130 during processing, a gas distribution system 108 to distribute one or more reactants to a surface of substrate 130, one or more reactant sources 110, 112, and optionally a carrier and/or purge gas source 114, fluidly coupled to reaction chamber 104 via lines 116-120 and valves or controllers 122-126. System 100 also includes a vacuum source 128.

In a typical gas-phase reactor, substrate 130 rests directly on top of susceptor 106 or, to facilitate removal of substrate 130, substrate 130 can be placed on top of pins or other protrusions extending from susceptor 106. Both approaches have corresponding drawbacks.

Whether a substrate 130 is place directly on top of susceptor 106 or on top of pins on the surface of the susceptor, gas flow (e.g., laminar gas flow) from gas distribution system 108, though a plenum 132, and to vacuum source 128 can be disrupted around the edge of the substrate due to the change in height from the top surface of the substrate to the top surface of the susceptor.

In addition, susceptors tend to be formed of a single material. Use of a single material has benefits, such as ease of manufacture, but also has drawbacks. For example, susceptors can be formed of metal, such as aluminum, which is easy to machine, exhibits high thermal conductivity, and is relatively inexpensive. However, metals, such as aluminum can generate contamination on the substrate and can be susceptible to corrosion, particularly during etch or clean processes. Other materials, which may be less susceptible to corrosion, such as silicon carbide, can also be used to form susceptor 106. However, silicon carbide is relatively expensive, is relatively brittle, and is relatively expensive to machine.

As noted above, susceptor 106 can include pins or other protrusions on which a substrate is placed. The protrusions can facilitate removal of substrate that might otherwise stick to susceptor 106, because of, for example, high static friction between substrate 130 and susceptor 160. However, use of such protrusions allows deposition and/or etching on a bottom surface of substrate 130, which can lead to various problems. In addition, heat transfer between susceptor 106 and substrate 130 is inhibited by use of pins, compared to heat transfer that can be obtained when substrate 130 is in direct contact with a top surface of susceptor 106. As a result, nonuniformity of deposition and etch rates across a surface of substrate 130 can increase with the use of pins. In addition, the protrusions can cause damage to a bottom surface of the substrate. Accordingly, improved devices, assemblies, and reactors for retaining substrates in gas-phase reactors are desired.

### SUMMARY OF THE DISCLOSURE

Various embodiments of the present disclosure relate to substrate trays, susceptor assemblies including the trays, and to gas-phase reactors including the substrate trays and/or assemblies. While the ways in which various embodiments of the present disclosure address drawbacks of prior susceptors and reactors are discussed in more detail below, in general, various embodiments of the disclosure provide a replaceable substrate tray formed of relatively non-reactive material that can distribute heat to a surface of a substrate, and to susceptor assemblies and reactors including the substrate tray. In addition, the substrate trays described herein allow for relatively easy replacement if, for example, contamination issues arise. Exemplary substrate trays and susceptor assemblies can also reduce manufacturing costs and can reduce change out times, which allows for quicker development iterations in a processing tool.

In accordance with exemplary embodiments of the disclosure, a substrate tray is formed of a nonmetal and is relatively non-reactive in a gas-phase reaction chamber environment. In accordance with exemplary aspects, the substrate tray includes a body comprising a relatively nonreactive material, such as a nonmetal, such as a material selected from one or more the group consisting of alumina, boron nitride, and silicon carbide; and a recess formed within a top surface of the body, the recess having a depth substantially equal a depth of a substrate and a recess surface for receiving a substrate. In accordance with further aspects, the recess surface includes at least a portion that is relatively smooth (e.g., an average roughness of 0.4 μm or less or 0.25 μm or less) to mitigate reactants reacting with a bottom surface of a substrate. The entire recess surface can be smooth or a portion thereof can be smooth (e.g., an outer perimeter of the recess surface). The recess surface in accordance with further aspects is relatively flat—e.g., to about 25 μm. The substrate tray can also include one or more recesses on a bottom surface to facilitate alignment of the substrate tray on a susceptor and/or to receive push pins from the susceptor to facilitate removal of the substrate from the susceptor. The susceptor can comprise, consist essentially of, or consist of a material selected from the group consisting of alumina, boron nitride, and silicon carbide, and combinations thereof. Alternatively, the susceptor can include material that is coated with one or more of alumina, boron nitride, and silicon carbide. By way of specific examples, the body can consist of silicon carbide, which can include sintered silicon carbide, silicon carbide formed using chemical vapor deposition, or sintered silicon carbide coated with silicon carbide deposited using chemical vapor deposition. The recess can be configured to receive, for example, a cylindrical substrate, such as a semiconductor wafer. In this case, the recess can be substantially cylindrical and slightly larger (e.g., greater than 0 mm and less than 5 mm, about 0.5 mm to about 5 mm, about 1 mm to about 4 mm, or about 2 mm) larger in diameter or other cross-sectional measurement. In accordance with yet further aspects of these embodiments, a thickness of the substrate tray is relatively small to facilitate heat transfer through the substrate tray. By way of examples, the substrate tray can be less than 5 mm thick, between a thickness of a substrate and about 5 mm think, between about 2 and 4.5 mm thick, between 3 mm and 4 mm think, or be about 3.5 mm thick. The substrate tray can include rounded edges at the top and/or bottom to facilitate removal and insertion of the substrate from and into the tray and/or removal and insertion of the substrate tray from or into the recess within the susceptor. Additionally or alternatively, the substrate tray can include one or more features, such as a notches, on a perimeter, such as an edge or a sidewall to facilitate removal of the tray from a susceptor.

In accordance with further exemplary embodiments, a susceptor assembly includes a substrate tray, such as a substrate tray as described herein, and a susceptor. In accordance with various aspects of these embodiments, the substrate tray is formed of a first material, and the susceptor is formed of a second material. For example, the susceptor can be formed of a material that is relatively inexpensive and easy to manufacture that can also have a relatively high thermal conductivity, but which might be reactive or that might otherwise contaminate a surface of the substrate if placed in direct contact with the substrate, such as aluminum. The susceptor can be formed of, for example, material that is less thermally conductive, but which is less reactive and/or prone to deposit or form contaminates on a surface of a substrate, such as the materials noted above. The assembly can be configured to promote laminar flow across an entire surface of the substrate by, for example, forming a recess in the susceptor, wherein a depth of the recess is approximately a height of the substrate tray and forming a recess within the substrate tray, wherein a depth of recess within the substrate tray is substantially equal the height of a substrate.

In accordance with yet additional embodiments of the disclosure, a gas-phase reactor includes a reaction chamber, a susceptor (such as a susceptor as described herein), and a substrate tray (such as a substrate tray as described herein). The gas-phase reactor can also include a vacuum source and/or one or more reactant sources coupled to the reaction chamber.

### BRIEF DESCRIPTION OF THE DRAWING FIGURES

A more complete understanding of exemplary embodiments of the present disclosure may be derived by referring to the detailed description and claims when considered in connection with the following illustrative figures.

FIG. 1 illustrates a prior-art gas-phase reactor system.

FIGS. 2(a)-2(e) illustrate a substrate tray in accordance with exemplary embodiments of the disclosure.

FIG. 3 illustrates a portion of a susceptor assembly in accordance with additional exemplary embodiments of the disclosure.

FIGS. 4 and 5 illustrate a reactor including a susceptor assembly in accordance with further exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments of substrate trays, susceptor assemblies, and reactors provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

The present disclosure generally relates to substrate trays, to susceptor assemblies including a substrate tray, and to gas-phase reactors including the substrate trays and/or assemblies. As set forth in more detail below, substrate trays as described herein can be used to process substrates, such as semiconductor wafers, in gas-phase reactors. Use of the substrate trays and assemblies including the trays is advantageous, because the trays can be formed of a relatively small amount of relatively non-reactant material, such that desired heat transfer to a substrate from a susceptor can still be obtained. Exemplary substrate trays can be removable or replaceable, such that the substrate trays can be removed to be cleaned or replaced—e.g., if damaged or broken, if contamination issues arise, and/or for process development. Additionally or alternatively, substrate trays can be interchangeable, to facilitate use of a susceptor with substrates of various sizes, while still promoting laminar flow of reactants across an entire surface of the substrate.

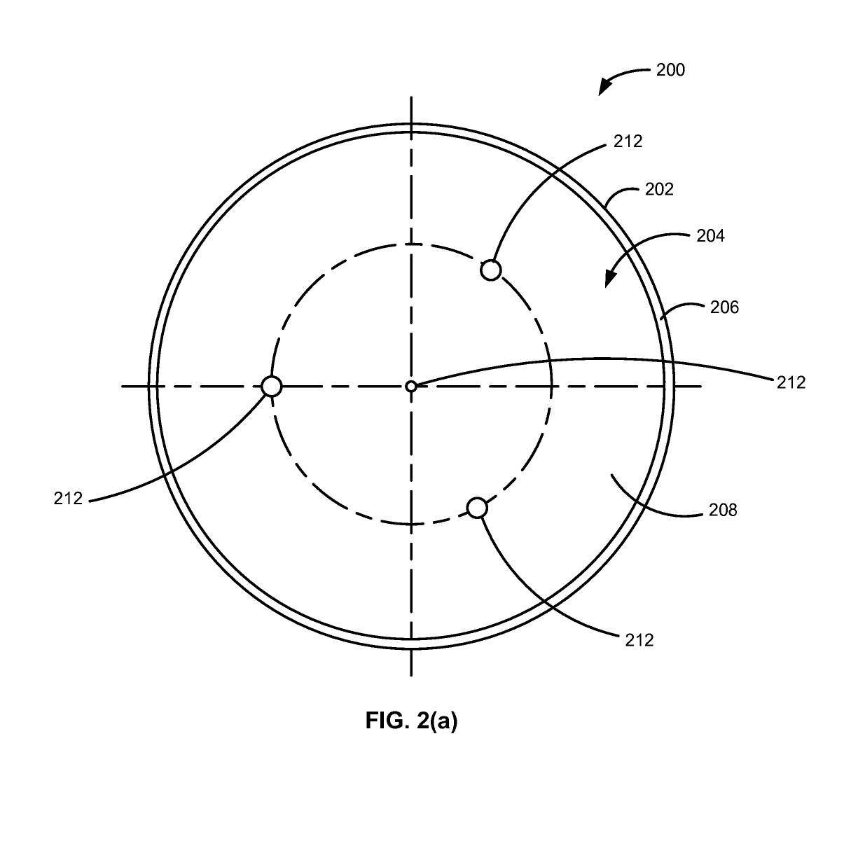

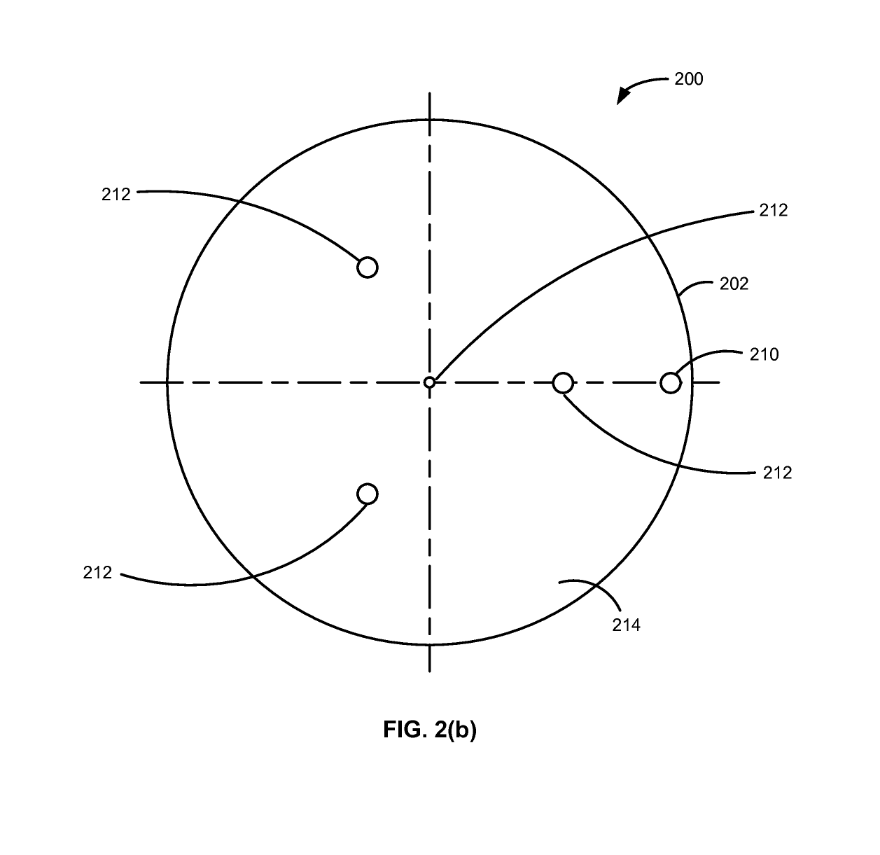

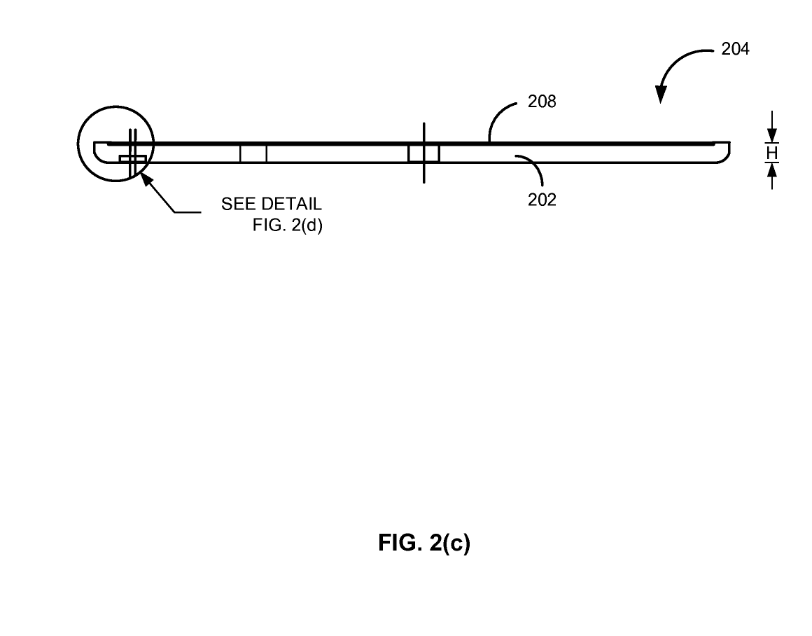

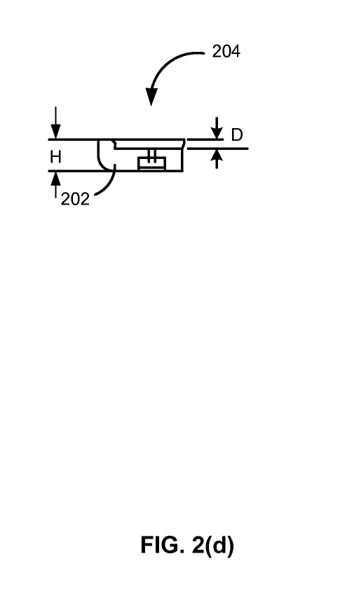

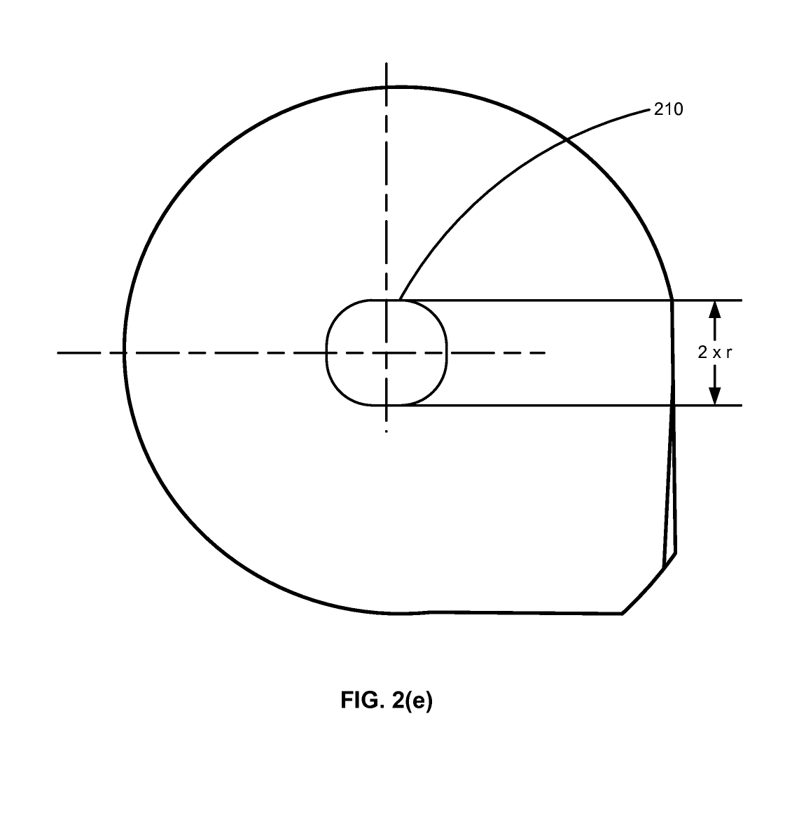

FIGS. 2(a)-2(e) illustrate an exemplary substrate tray 200 in accordance with exemplary embodiments of the disclosure. FIG. 2(a) illustrates a top plan view of substrate tray 200. FIG. 2(b) illustrates a bottom plan view of substrate tray 200. FIG. 2(c) illustrates a side view of substrate tray 200. FIG. 2(d) illustrates a close-up cross-sectional view of an edge of substrate tray 200. And, FIG. 2(e) illustrates a close-up view of an alignment recess of substrate tray 200.

As discussed in more detail below, substrate tray 200 is configured to fit within a recess of a susceptor to form part of a susceptor assembly. Use of a susceptor tray is advantageous over use of a unitary or monolithic susceptor, because it allows the susceptor tray to be formed of a different (second) material compared to a first material used to form the susceptor, which provides the assemblies of the present disclosure with advantages over prior art assemblies.

Substrate tray 200 includes a body 202 having a recess 204 formed therein. In accordance with various embodiments of the disclosure, body 202 is formed of a relatively non-reactive material, such as a nonmetal material. Exemplary materials suitable for body 202 include oxides and nitrides, including one or more of the group consisting of alumina, boron nitride, and silicon carbide. Body 202 can comprise, consist essentially of, or consist of such materials. By way of particular examples, body 202 includes silicon carbide. In these cases, body 202 can be formed of sintered silicon carbide, silicon carbide formed using, gas-phase processing, such as chemical vapor deposition, or of sintered silicon carbide coated with gas-phase deposition (e.g., CVD deposition) of silicon carbide.

A thickness of body 202 can vary according to a substrate to be processed using substrate tray 200. By way of examples, a thickness, indicated as “H” in FIG. 2(c), can range from greater than 0 to less than 5 mm, between about 2 and 4.5 mm thick, between 3 mm and 4 mm think, or be about 3.5 mm thick.

Recess 204 is formed within a top surface of the body 206. Recess 204 is configured to retain a substrate 306 in place during processing. In accordance with various embodiments of the disclosure, recess 204 has a depth, illustrated as “D” in FIG. 2(d) substantially equal to a height of a substrate. Recess 204 also includes a recess surface 208 for receiving a substrate. In accordance with further aspects, recess surface 208 includes at least a portion that is relatively smooth (e.g., an average roughness of 0.4 μm or less or 0.25 μm or less) to mitigate reactants reacting with a bottom surface of a substrate. The entire recess surface can be smooth or a portion thereof can be smooth (e.g., an outer perimeter of the recess surface). By way of examples, at least a portion of entire recess surface is relatively smooth and has an average roughness of 0.4 μm or less or 0.25 μm or less. Additionally or alternatively, recess surface 208 can be relatively flat—e.g., to 25 μm or less.

Recess 204 can be shaped, such that a perimeter of recess 204 substantially follows a perimeter of a substrate. By way of example, when a substrate is a substantial cylinder (e.g., a wafer), then recess 204 can have a shape of a shallow cylinder, having a height substantially equal the height of the substrate, and a diameter slightly larger (e.g., greater than 0 mm and less than 5 mm, about 0.5 mm to about 5 mm, about 1 mm to about 4 mm, or about 2 mm) larger in diameter or other cross-sectional measurement.

With reference to FIG. 2(b), substrate tray 200 includes one or more recesses 210 formed within a bottom surface 214 of body 202, wherein the one or more recesses 210 formed within a bottom surface 214 of the body can be used to facilitate alignment of the substrate tray on a susceptor. FIG. 2(e) illustrates a close-up view of an exemplary recess 210 suitable for alignment. In the illustrated example, recess 210 does not extend through a thickness H of body 202 and is an elongated hole having a radius (r) of about 3.3 mm and a long axis of about 4.3 mm.

Substrate tray 200 can also include recesses 212, which can be through holes. Recesses 212 can, for example, receive push pins from a susceptor that push a substrate from a susceptor to thereby overcome force retaining the substrate to recess surface 208 and/or to otherwise facilitate transfer of the substrate from recess surface 208—e.g., using automated equipment. Additionally or alternatively recesses 212 can be used to align substrate tray 200 on a susceptor.

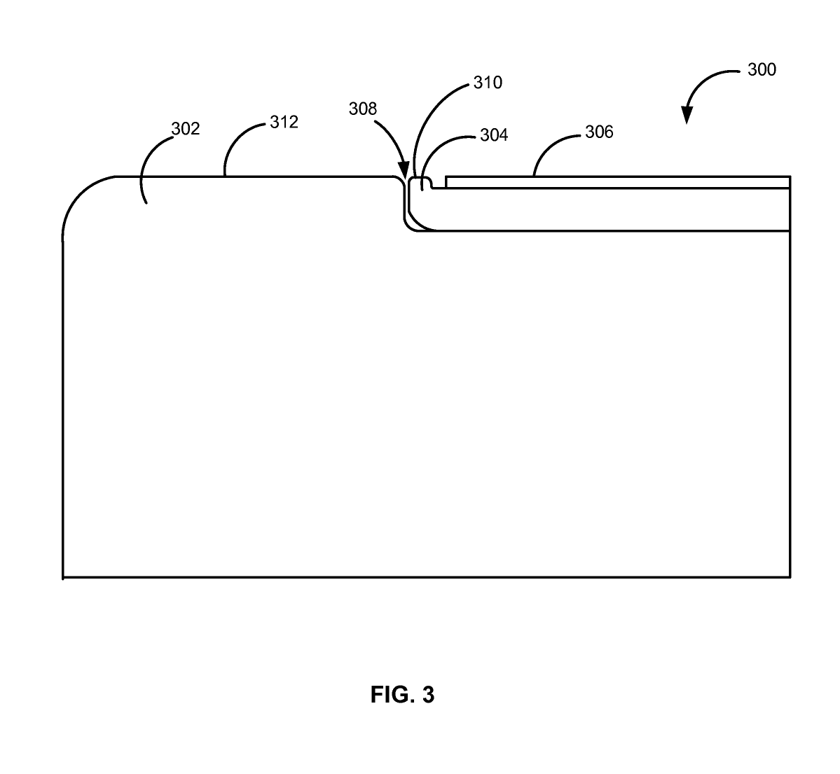

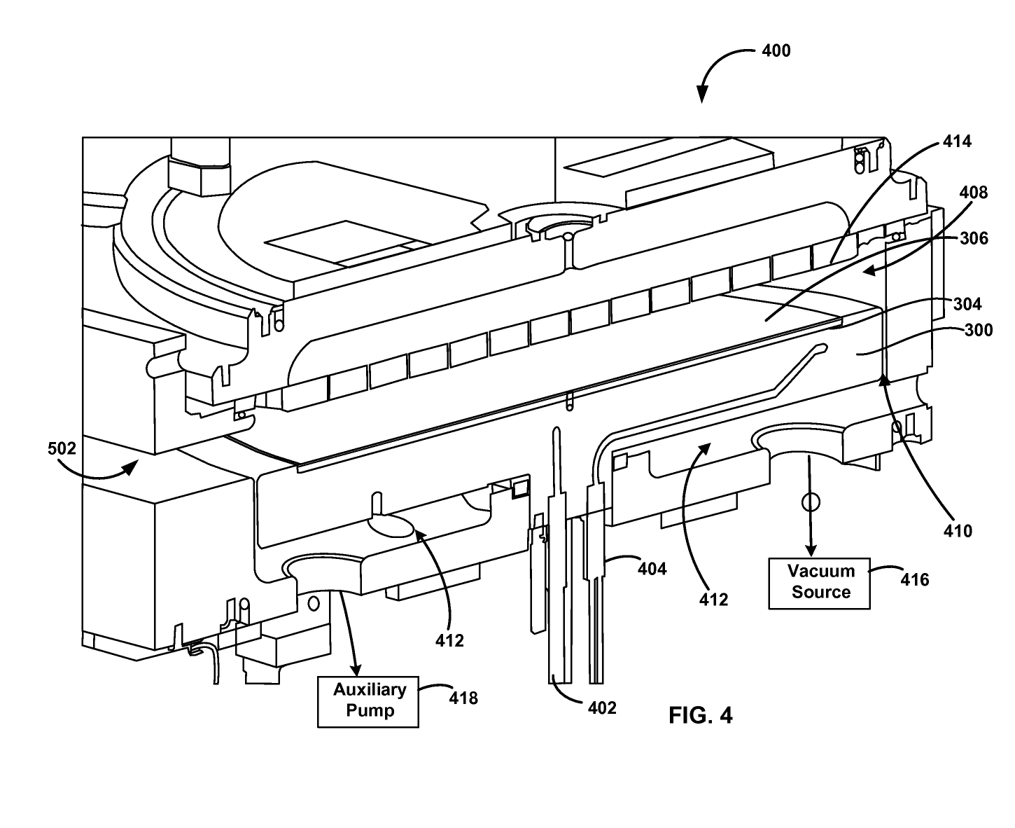

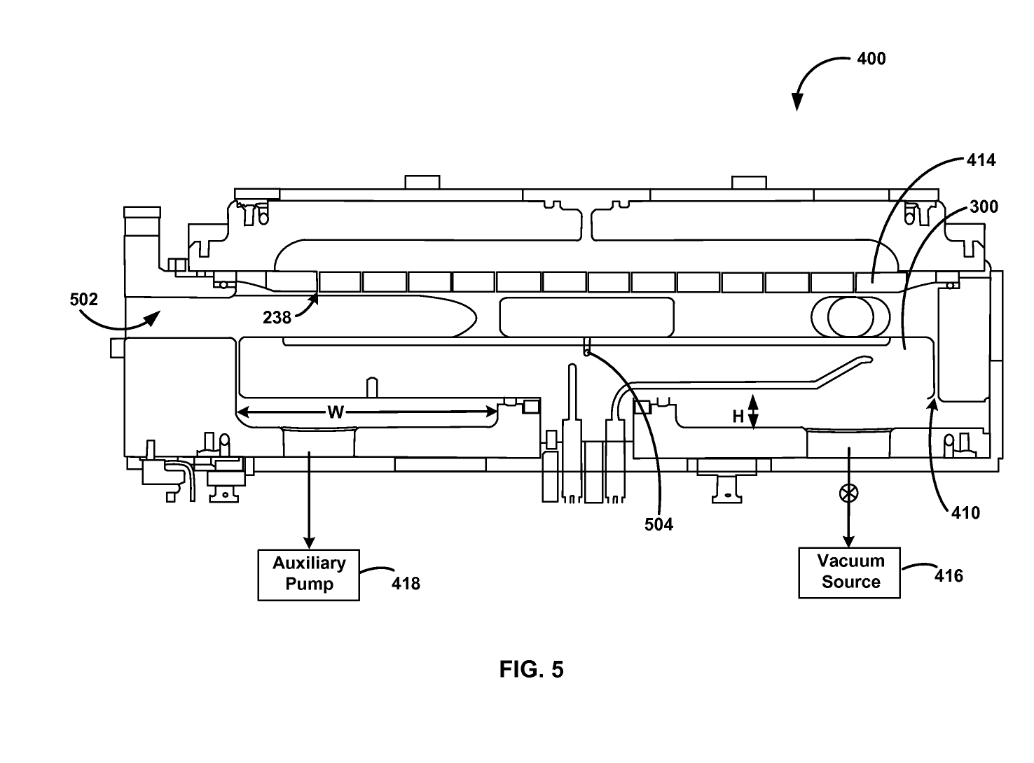

FIG. 3 illustrates a portion of a susceptor assembly 300 and FIGS. 4 and 5 illustrate a reactor 400 including susceptor assembly 300. Assembly 300 includes a susceptor 302 and a substrate tray 304.

Susceptor 302 is configured to receive and retain substrate 306 in place during processing, such as during a deposition or etch process. Exemplary susceptor 302 includes a recess 308 to receive substrate tray 304, such that a top surface of substrate tray 310 is substantially coplanar with a top surface of the susceptor 312. This allows substantially laminar flow across the surface of substrate tray 310 and the surface of the susceptor 312. As used herein “substantially” includes the value plus or minus ten percent or plus or minus five percent, unless otherwise noted. Susceptor 302 can also include temperature measurement devices 402, 404 and or heating and/or cooling elements (not illustrated). Use of heating elements allows reactor 400 to operate in a cold wall/hot substrate mode to reduce undesired deposition or etch on walls of a reaction chamber.

In accordance with various embodiments of the invention recess 308 is slightly larger than substrate tray 304. By way of examples, diameter or similar cross section of recess 308 is greater than 0 mm and less than 5 mm, about 0.5 mm to about 5 mm, about 1 mm to about 4 mm, or about 2 mm larger in diameter or similar cross section of substrate tray 304. Recess 308 can be substantially the same shape as substrate tray 304. By way of examples, recess 308 is substantially a cylinder.

Susceptor 302 can be formed of a variety of materials. Susceptor 302 can advantageously be formed of a material that is relatively easy to machine and that also has a high thermal conductivity, such as aluminum, nickel coated aluminum, nickel, and nickel alloys.

Substrate tray 304 can be the same or similar as substrate tray 200. As noted above, substrate tray 200 can be configured, such that when a substrate is placed within recess 204, the top of the substrate is substantially coplanar with top surface 206. Thus, assembly 300 can be configured such that a top surface of susceptor 312 is substantially coplanar with the top surface of substrate 306.

In accordance with various examples of the disclosure, susceptor 302 is fixedly attached to reactor 400 and does not move relative to reaction chamber 408 to receive or allow removal of substrate 306. Rather, substrates can be loaded onto or removed from susceptor assembly 300 though an opening 502 in a sidewall of reactor 400. This allows a simplified, less expensive design of reactor 400 compared to similar reactors.

Susceptor assembly 300 can also include lift pins formed of, for example, a nonmetal, such as an oxide or a nitride (e.g., silicon carbide) and/or one or more alignment pins, such as pin 504 formed of the same or similar material.

With reference now to FIGS. 4 and 5, reactor 400 can be any suitable gas-phase reactor. For example, reactor 400 can be a chemical vapor deposition (CVD) reactor, a plasma-enhance CVD (PECVD) reactor, an atomic layer deposition (ALD) reactor, an epitaxial reactor, or the like. By way of example, reactor 400 is an etch reactor.

Reactor 400 includes reaction chamber 408, susceptor assembly 300, a channel 410, and an exhaust plenum 412. In the illustrated example, reactor 400 also includes a gas distribution system 414, such as a shower head or a cross-flow gas distribution system. An exemplary reactor suitable for use with assembly 300 and substrate tray 200 is described in application Ser. No. 14/219,839 entitled “GAS-PHASE REACTOR AND SYSTEM HAVING EXHAUST PLENUM AND COMPONENTS THEREOF”, filed on Mar. 19, 2014, the contents of which are incorporated herein by reference to the extent such contents do not conflict with the present disclosure.

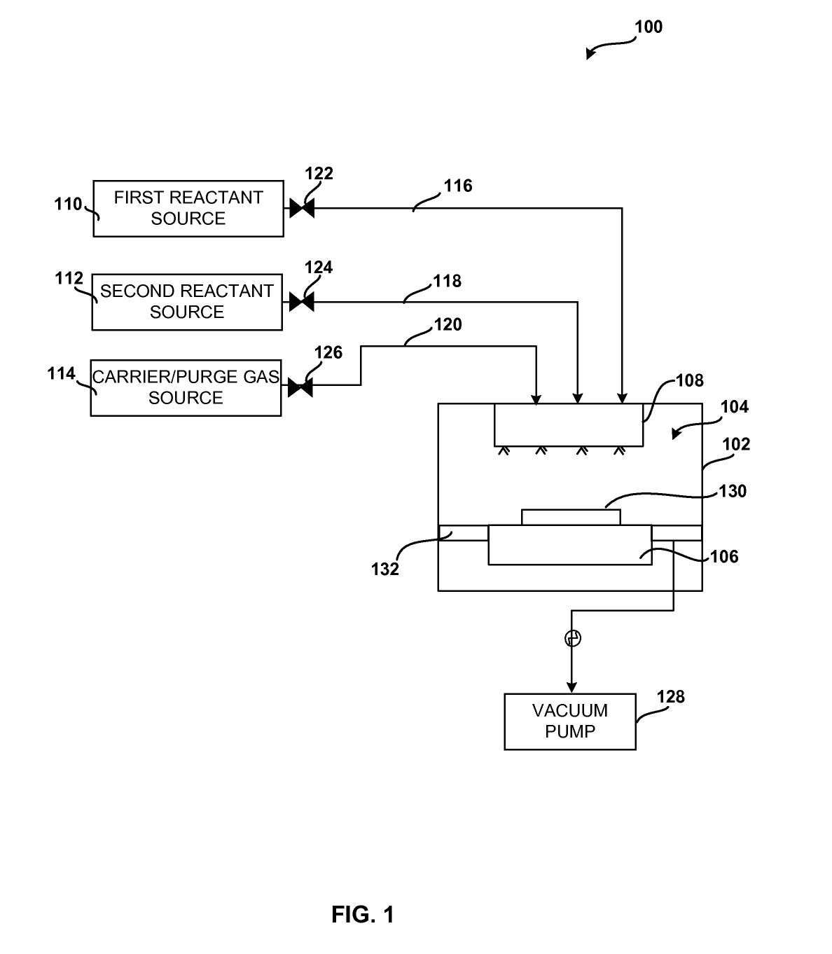

A system in accordance with yet further exemplary embodiments of the disclosure includes a reactor, such as reactor 400, a vacuum source, such as vacuum source 416 or 418, and one or more reactant sources, such as sources 110, 112 described above in connection with FIG. 1.

Although exemplary embodiments of the present disclosure are set forth herein, it should be appreciated that the disclosure is not so limited. For example, although the substrate trays, susceptor assemblies, and reactors are described in connection with various specific configurations, the disclosure is not necessarily limited to these examples. Various modifications, variations, and enhancements of the system and method set forth herein may be made without departing from the spirit and scope of the present disclosure.

The subject matter of the present disclosure includes all novel and nonobvious combinations and subcombinations of the various reactors, systems, components, and configurations, and other features, functions, acts, and/or properties disclosed herein, as well as any and all equivalents thereof.

We claim:

1. A substrate tray comprising:
a body comprising a material selected from one or more of the group consisting of alumina, boron nitride, and silicon carbide; and
a recess formed within a top surface of the body, the recess having a depth substantially equal to a depth of a substrate and a recess surface for receiving a substrate.

2. The substrate tray of claim 1, further comprising one or more recesses formed within a bottom surface of the body, wherein the one or more recesses formed within a bottom surface of the body facilitate alignment of the substrate tray on a susceptor.

3. The substrate tray of claim 1, wherein an average surface roughness of the recess surface is less than or equal to 0.4 μm.

4. The substrate tray of claim 1, wherein an average surface roughness of the recess surface is less than or equal to 0.25 μm.

5. The substrate tray of claim 1, wherein the body is coated with a material selected from the group consisting of alumina, boron nitride, and silicon carbide.

6. The substrate tray of claim 1, wherein a shape of the recess substantially comprises a cylinder having a diameter.

7. The substrate tray of claim 1, wherein the body comprises silicon carbide.

8. The substrate tray of claim 1, wherein a thickness of the body is less than or equal to 5 mm.

9. A susceptor assembly comprising:
a susceptor comprising a first material, the susceptor having a first recess; and
a substrate tray comprising a second material and having a second recess, the substrate tray within the first recess, such that a top surface of the substrate tray is substantially coplanar with a top surface of the susceptor, and the second recess comprising a recess surface.

10. The susceptor assembly of claim 9, wherein the first material is selected from the group consisting of aluminum, nickel coated aluminum, nickel, and nickel alloys.

11. The susceptor assembly of claim 9, wherein the second material is selected from the group consisting of alumina, boron nitride, and silicon carbide.

12. The susceptor assembly of claim 9, wherein an average surface roughness of the recess surface is less than or equal to 0.4 μm.

13. The susceptor assembly of claim 9, wherein an average surface roughness of the recess surface is less than or equal to 0.25 μm.

14. The susceptor assembly of claim 9, wherein the second recess comprises a height substantially equal to a height of the substrate tray.

15. The susceptor assembly of claim 9, further comprising one or more alignment pins, wherein the one or more alignment pins are received by a top portion of the susceptor and a bottom portion of the substrate tray.

16. The susceptor assembly of claim 9, further comprising one or more lift pins, wherein the lift pins protrude from a top surface of the susceptor, and are received by one or more holes through the recess surface.

17. The susceptor assembly of claim 9, wherein the first material comprises silicon carbide.

18. A gas-phase reactor comprising:
a reactor comprising a reaction chamber;
a susceptor comprising a first material, the susceptor having a first recess; and
a substrate tray comprising a second material and having a second recess, the substrate tray within the first recess, such that a top surface of the substrate tray is substantially coplanar with a top surface of the susceptor, and the second recess comprising a recess surface.

19. The gas-phase reactor of claim 18, further comprising a vacuum source coupled to the reaction chamber.

20. The gas-phase reactor of claim 18, further comprising one or more reactant sources coupled to the reaction chamber.
